(19) United States
(12) Patent Application Publication
(10) Pub. No.: US 2024/0321631 A1
(43) Pub. Date: Sep. 26, 2024

(54) BACK-END-OF-LINE (BEOL) INTERCONNECTS WITH DIFFERENT AIRGAP HEIGHTS AND METAL TRACE CORNER PROTECTION STRUCTURES

(71) Applicant: QUALCOMM Incorporated, San Diego, CA (US)

(72) Inventors: Xia LI, San Diego, CA (US); Junjing BAO, San Diego, CA (US); Bin YANG, San Diego, CA (US); Biswa Ranjan PANDA, Bangaluru (IN); Ramesh MANCHANA, Hyderabad (IN)

(21) Appl. No.: 18/190,024

(22) Filed: Mar. 24, 2023

(51) Int. Cl. H01L 21/768; H01L 23/522; H01L 23/532

(52) U.S. Cl. CPC H01L 21/7682; H01L 21/76802; H01L 21/76829; H01L 21/76877; H01L 23/5226; H01L 23/53257; H01L 23/5329

(57) ABSTRACT

An integrated circuit (IC) includes back-end-of-line (BEOL) interconnects in a first intermetal dielectric (IMD) layer on a substrate. The IC also includes second BEOL interconnects on the first IMD layer, coupled to the first BEOL interconnects through first BEOL vias in the first IMD layer. The IC further includes a second IMD layer on the second BEOL interconnects to seal airgaps between the plurality of second BEOL interconnects. The IC also includes etch stop spacers on portions of sidewalls of the second BEOL interconnects to separate the portions of the sidewalls from the second IMD layer. The IC further includes third BEOL interconnects on the second IMD layer and coupled to one or more of the second BEOL interconnects through second BEOL vias in the second IMD layer.

### BACKGROUND

### Field

Aspects of the present disclosure relate to semiconductor devices and, more particularly, to back-end-of-line (BEOL) interconnects with different airgap heights and metal trace corner protection structures.

### Background

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the large number of devices that are now interconnected in a modern electronic device. The increased number of interconnect levels for supporting the increased number of devices involves more intricate processes.

The design of complex system-on-chips (SoCs) may be affected by parasitic resistance and capacitance due to layer-to-layer interconnects. That is, dynamic performance of complex SoCs (e.g., an alternating current (AC) performance) may be detrimentally affected by parasitic resistance and capacitance generated by layer-to-layer interconnects. SoC circuit design techniques that address parasitic resistance and capacitance from layer-to-layer interconnections are desired.

### SUMMARY

An integrated circuit (IC) includes back-end-of-line (BEOL) interconnects in a first intermetal dielectric (IMD) layer on a substrate. The IC also includes second BEOL interconnects on the first IMD layer, coupled to the first BEOL interconnects through first BEOL vias in the first IMD layer. The IC further includes a second IMD layer on the second BEOL interconnects to seal airgaps between the plurality of second BEOL interconnects. The IC also includes etch stop spacers on portions of sidewalls of the second BEOL interconnects to separate the portions of the sidewalls from the second IMD layer. The IC further includes third BEOL interconnects on the second IMD layer and coupled to one or more of the second BEOL interconnects through second BEOL vias in the second IMD layer.

A method for fabricating back-end-of-line (BEOL) interconnects with different airgap heights and metal trace corner protection structures is described. The method includes forming a plurality of second back-end-of-line (BEOL) interconnects on a first intermetal dielectric (IMD) layer, coupled to a plurality of first BEOL interconnects by first BEOL vias in the first IMD layer. The method also includes recess etching selected ones of the plurality of second BEOL interconnects. The method further includes depositing a sacrificial material on each of the second BEOL interconnects and the first IMD layer. The method also includes recess etching portions of the sacrificial material to expose portions of sidewalls of the second BEOL interconnects through a sacrificial material layer. The method further includes forming an etch stop spacer on the exposed portions of sidewalls of the second BEOL interconnects. The method also includes thermally removing the sacrificial material layer to provide airgaps between the plurality of second BEOL interconnects. The method further includes forming second BEOL vias on selected ones of the second BEOL interconnects.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a system-on-chip (SoC), including back-end-of-line (BEOL) interconnects with different airgap heights and metal trace corner protection structures, in accordance with certain aspects of the present disclosure.

FIG. 2 is a block diagram illustrating a cross-section of an integrated circuit (IC) device including an interconnect stack of back-end-of-line (BEOL) layers.

FIG. 3 shows a cross-sectional view illustrating an integrated circuit (IC) device, having back-end-of-line (BEOL) interconnects with different airgap heights and metal trace corner protection structures, according to aspects of the present disclosure.

FIGS. 4A-4K are block diagrams illustrating formation of the integrated circuit (IC) device of FIG. 3, according to aspects of the present disclosure.

FIG. 5 shows a cross-sectional view illustrating an integrated circuit (IC) device, having back-end-of-line (BEOL) interconnects with different airgap shapes, according to aspects of the present disclosure.

FIGS. 6A-6H are cross-sectional diagrams illustrating formation of the integrated circuit (IC) device of FIG. 5, according to aspects of the present disclosure.

FIG. 7 is a process flow diagram illustrating a method for fabricating back-end-of-line (BEOL) interconnects with airgaps and metal trace corner protection structures, according to aspects of the present disclosure.

FIG. 8 is a block diagram showing an exemplary wireless communications system in which a configuration of the disclosure may be advantageously employed.

FIG. 9 is a block diagram illustrating a design workstation used for circuit, layout, and logic design of a semiconductor component, according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described herein, the use of the term “and/or” is intended to represent an “inclusive OR,” and the use of the term “or” is intended to represent an “exclusive OR.” As described herein, the term “exemplary” used throughout this description means “serving as an example, instance, or illustration,” and should not necessarily be construed as preferred or advantageous over other exemplary configurations. As described herein, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described herein, the term “proximate” used throughout this description means “adjacent, very near, next to, or close to.” As described herein, the term “on” used throughout this description means “directly on” in some configurations, and “indirectly on” in other configurations.

A system hierarchy includes interconnection of active devices at a lowest system level all the way up to system level interconnections at a highest level. Electrical connections exist at each of the levels of the system hierarchy to connect different devices together on an integrated circuit. As integrated circuits become more complex, however, more interconnect layers are used to provide the electrical connections between the devices. More recently, the number of interconnect levels for circuitry has increased due to the substantial number of devices that are now interconnected in a modern electronic device.

These interconnections include back-end-of-line (BEOL) interconnect layers, which may refer to the conductive interconnect layers (e.g., a first BEOL interconnect layer or metal one (M1), metal two (M2), metal three (M3), metal four (M4), etc.) for electrically coupling to front-end-of-line active devices of an integrated circuit. The various BEOL interconnect layers are formed at corresponding back-end-of-line interconnect levels, in which lower BEOL interconnect levels use thinner metal layers relative to upper BEOL interconnect levels. The BEOL interconnect layers may electrically couple to middle-of-line interconnect layers, for example, to connect M1 to an oxide diffusion (OD) layer of an integrated circuit.

The design of complex system-on-chips (SoCs) may be affected by parasitic resistance and capacitance due to layer-to-layer interconnects. That is, performance of complex SoCs (e.g., a resistance-capacitance (RC) performance) may be detrimentally affected by parasitic resistance and capacitance generated by layer-to-layer interconnects, such as metal traces formed from BEOL interconnect layers. SoC circuit design techniques that address parasitic resistance and capacitance from layer-to-layer interconnections are desired.

Various aspects of the present disclosure provide back-end-of-line (BEOL) interconnects with different airgap heights and metal trace corner protection structures. A process flow for fabrication of interconnects with different airgap heights and metal trace corner protection structures may include front-end-of-line (FEOL) processes, middle-of-line (MOL) processes, and BEOL processes. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. Similarly, the terms “chip” and “die” may be used interchangeably.

According to aspects of the present disclosure, a resistance-capacitance (RC) performance of an SoC is improved by fabricating BEOL interconnects with different airgap heights and metal trace corner protection structures. In some aspects of the present disclosure, an integrated circuit (IC) includes first BEOL interconnects on a substrate, and a first intermetal dielectric (IMD) layer on the first BEOL interconnects. Additionally, the IC includes second BEOL interconnects on the first IMD layer and coupled to the first BEOL interconnects through first BEOL vias in the first IMD layer. In some aspects of the present disclosure, the IC includes a second IMD layer on the second BEOL interconnects to seal airgaps between the second BEOL interconnects. In some aspects of the present disclosure, the IC further includes a spacer material on portions of sidewalls of the second BEOL interconnects to separate the portions of the sidewalls from the second IMD layer. The IC also includes third BEOL interconnects on the second IMD layer and coupled to some of the second BEOL interconnects through second BEOL vias in the second IMD layer.

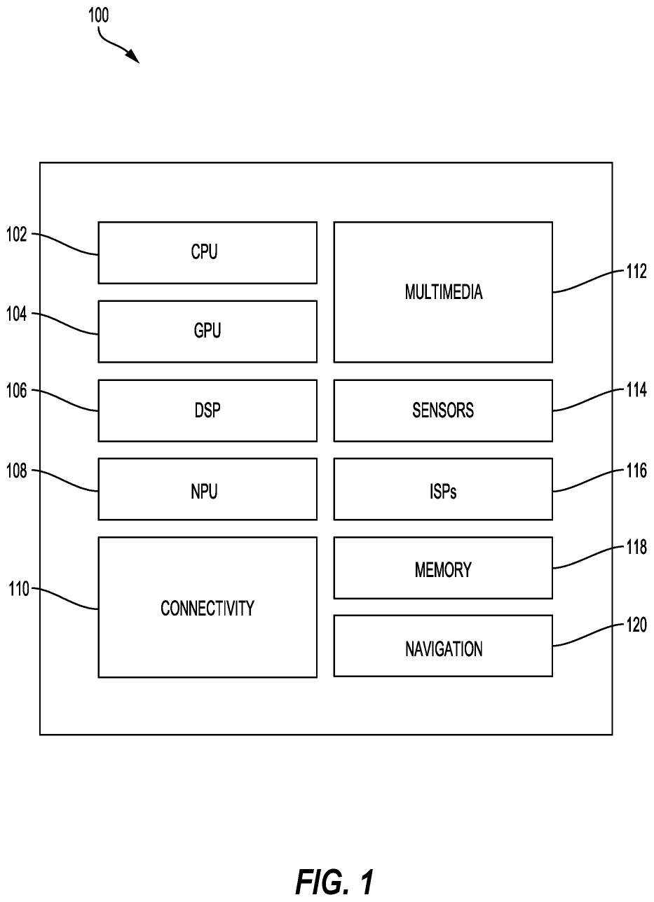

FIG. 1 illustrates an example implementation of a host system-on-chip (SoC) 100, which includes back-end-of-line (BEOL) interconnects with different airgap heights and metal trace corner protection structures, in accordance with aspects of the present disclosure. The host SoC 100 includes processing blocks tailored to specific functions, such as a connectivity block 110. The connectivity block 110 may include sixth generation (6G), connectivity fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system, and a memory 118. The multi-core CPU 102, the GPU 104, the DSP 106, the NPU 108, and the multimedia engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU 108 may be based on an ARM instruction set.

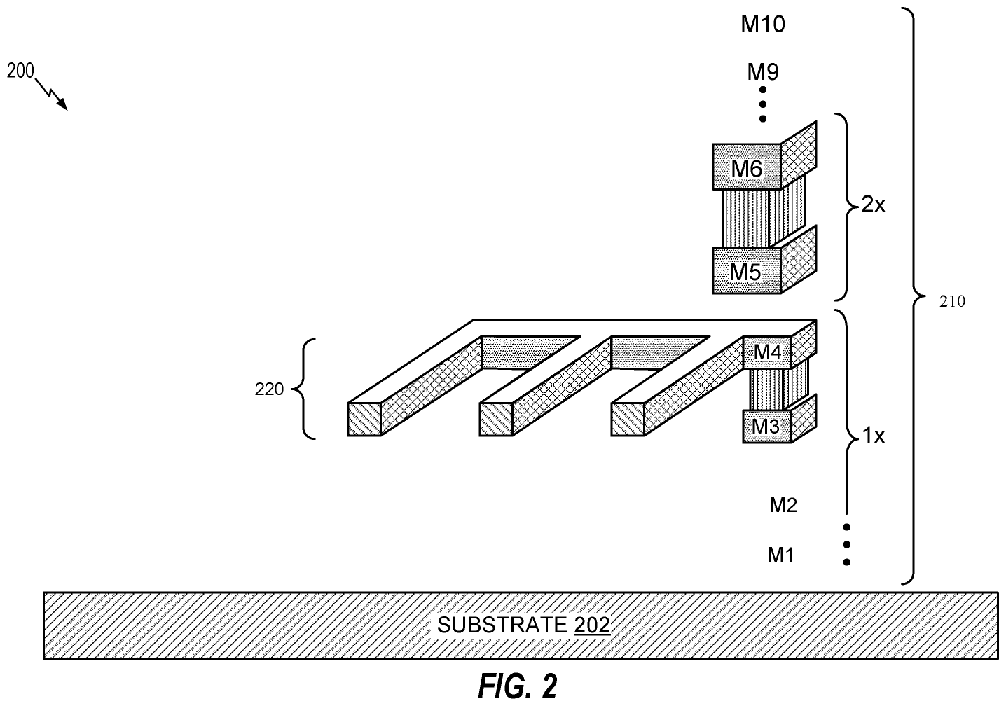

FIG. 2 is a block diagram illustrating a cross-section of an integrated circuit (IC) device 200 including an interconnect stack 210. The interconnect stack 210 of the IC device 200 includes multiple back-end-of-line (BEOL) conductive interconnect layers (M1, . . . , M9, M10) on a semiconductor substrate 202 (e.g., a diced silicon wafer). The semiconductor substrate 202 may be fabricated to include an active device layer (not shown) using complementary metal oxide semiconductor (CMOS) technology. The various BEOL interconnect layers are formed at corresponding BEOL interconnect levels, in which lower BEOL interconnect levels (e.g., M1) use thinner metal layers relative to upper (e.g., M9) BEOL interconnect levels. In this example, an interconnect structure 220 is formed at an M2 interconnect layer, between M1 and M3, or an M4 interconnect layer, between M3 and M5 interconnect layers.

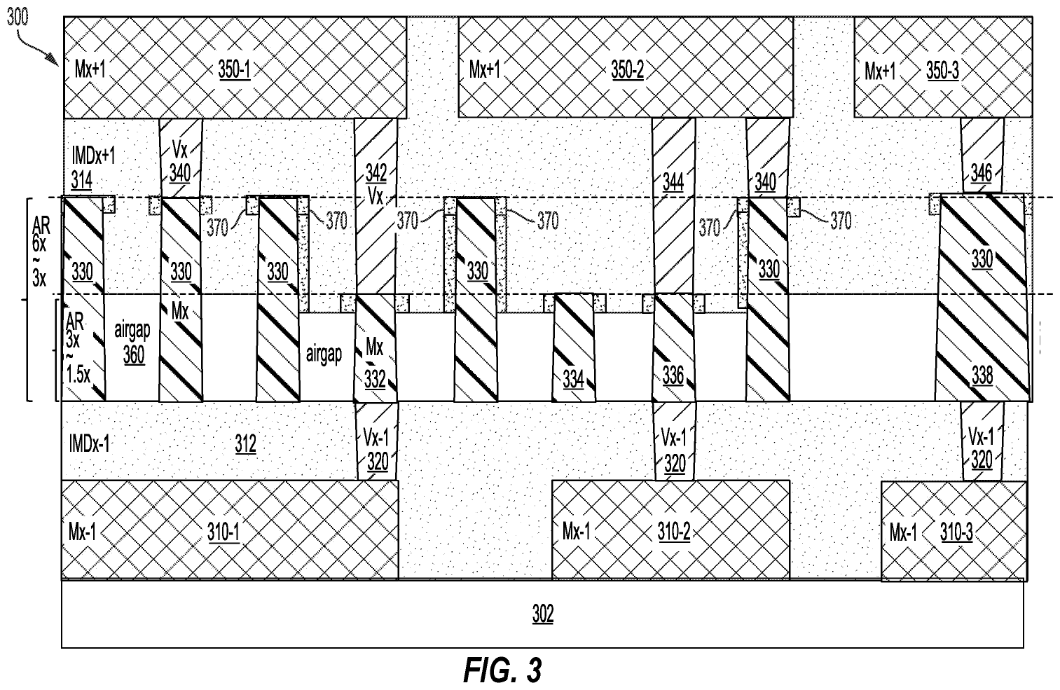

The design of complex system-on-chips (SoCs) may be affected by parasitic resistance and capacitance due to layer-to-layer interconnects. That is, performance of complex SoCs (e.g., a resistance-capacitance (RC) performance) may be detrimentally affected by parasitic resistance and capacitance generated by layer-to-layer interconnects, such as metal traces formed from BEOL interconnect layers. SoC circuit design techniques that address parasitic resistance and capacitance from layer-to-layer interconnections are desired. Some aspects of the present disclosure provide BEOL interconnects with different airgap heights and metal trace corner protection structures, for example, as shown in FIG. 3.

FIG. 3 shows a cross-sectional view illustrating an integrated circuit (IC) device 300, having back-end-of-line (BEOL) interconnects with different airgap heights and metal trace corner protection structures, according to aspects of the present disclosure. The IC device 300 includes a semiconductor substrate (e.g., a silicon wafer) 302 on which first BEOL (Mx−1) interconnects 310 (310-1, 310-2, 310-3) are formed. In some aspects of the present disclosure, the IC device 300 includes second BEOL (Mx) interconnects 330, 332, 334, 336, 338 on a first intermetal dielectric (IMDx−1) layer 312, and coupled to the Mx−1 interconnects 310 (310-1, 310-2, 310-3) through first BEOL (Vx−1) vias 320 in the IMDx−1 layer 312.

In some aspects of the present disclosure, the IC device 300 includes a third IMD (IMDx+1) layer 314 on the Mx interconnects 330 to seal airgaps 360 between the Mx interconnects 330. In some aspects of the present disclosure, the IC device 300 further includes a spacer material on portions of sidewalls of the Mx interconnects 330 to provide etch stop spacers 370 that separate the portions of the sidewalls from the IMDx+1 layer 314. The IC device 300 also includes third BEOL (Mx+1) interconnects 350 (350-1, 350-2, 350-3) on the IMDx+1 layer 314 and coupled to some of the Mx interconnects 330 through second BEOL (Vx) vias 340, 342, 344, 346 in the IMDx+1 layer 314.

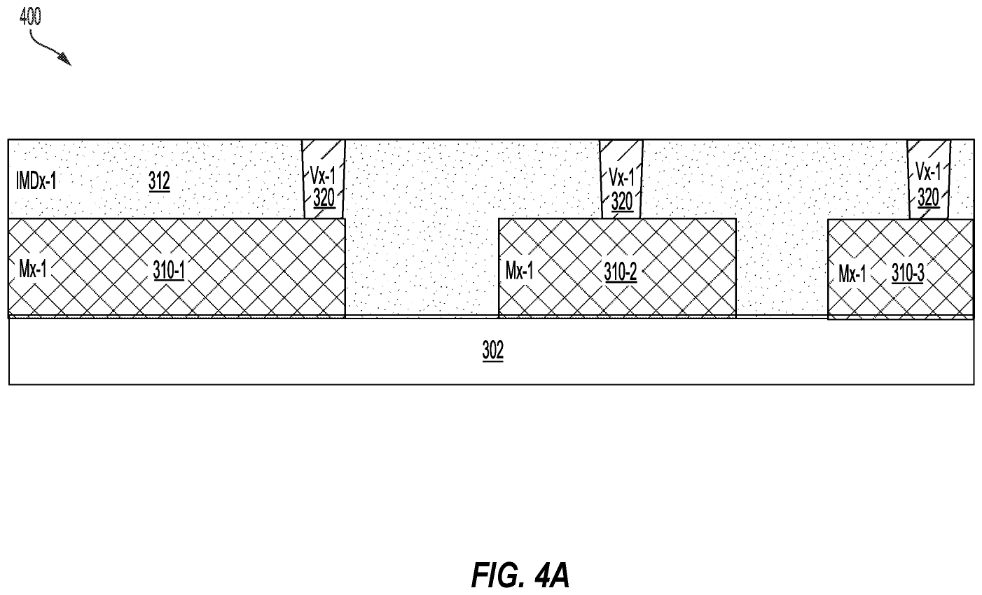

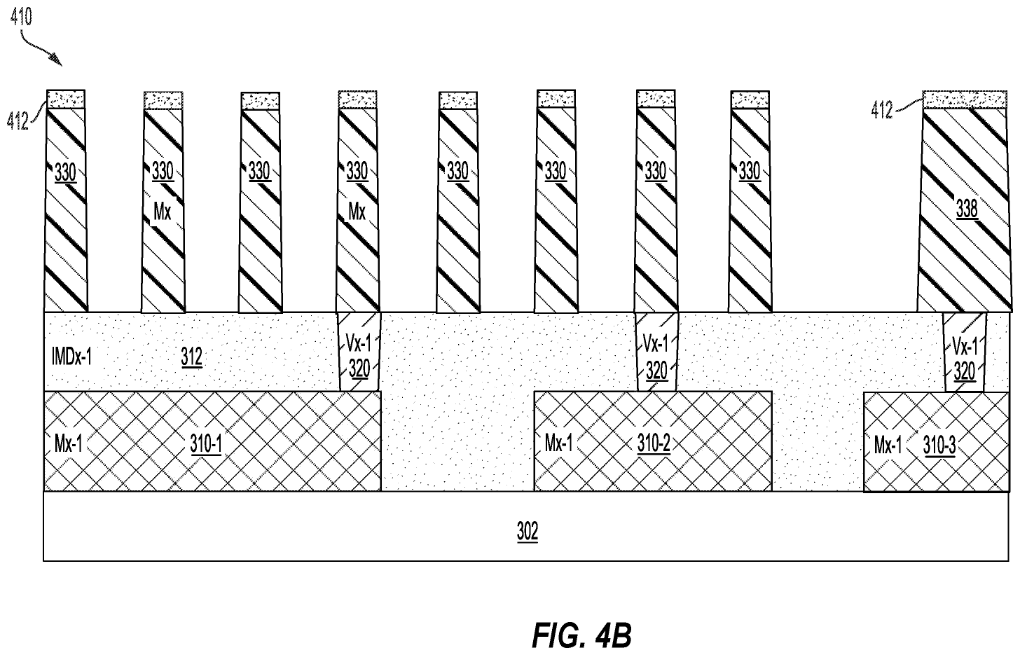

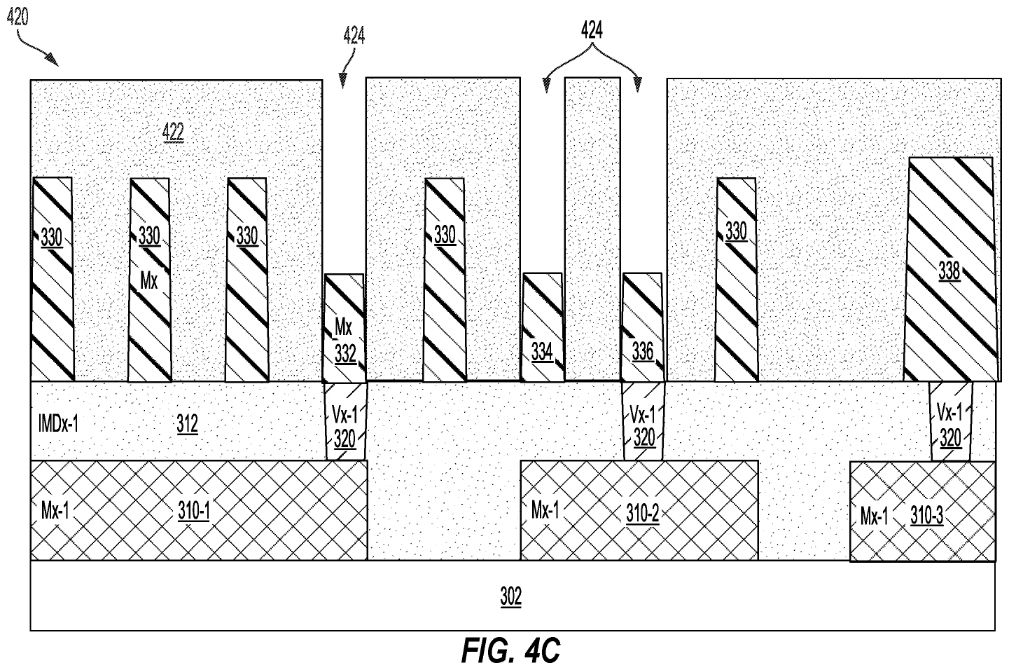

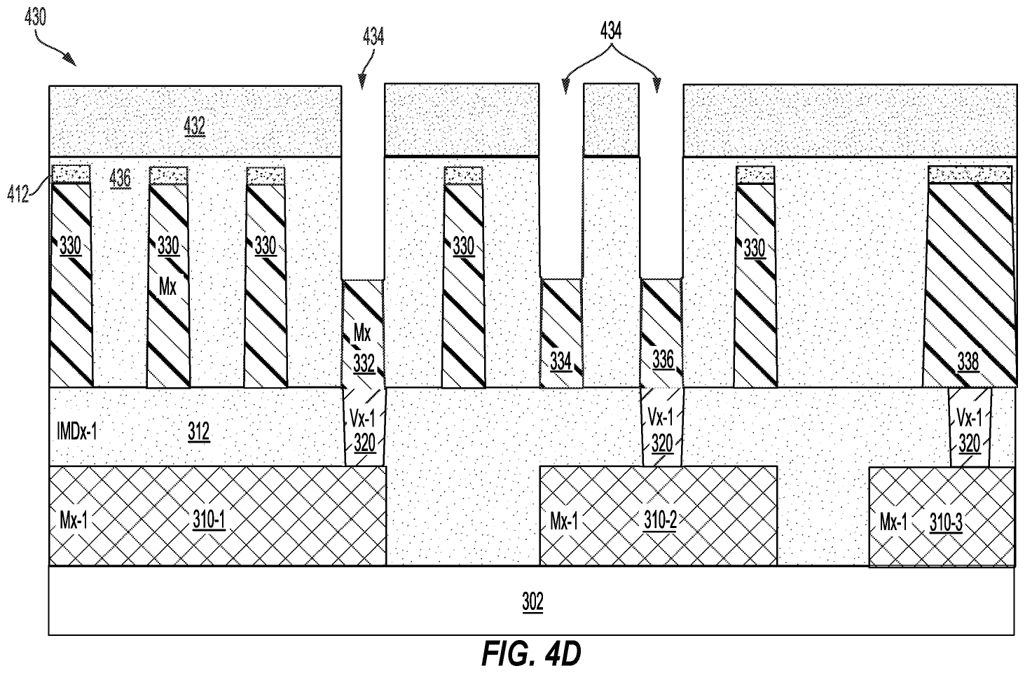

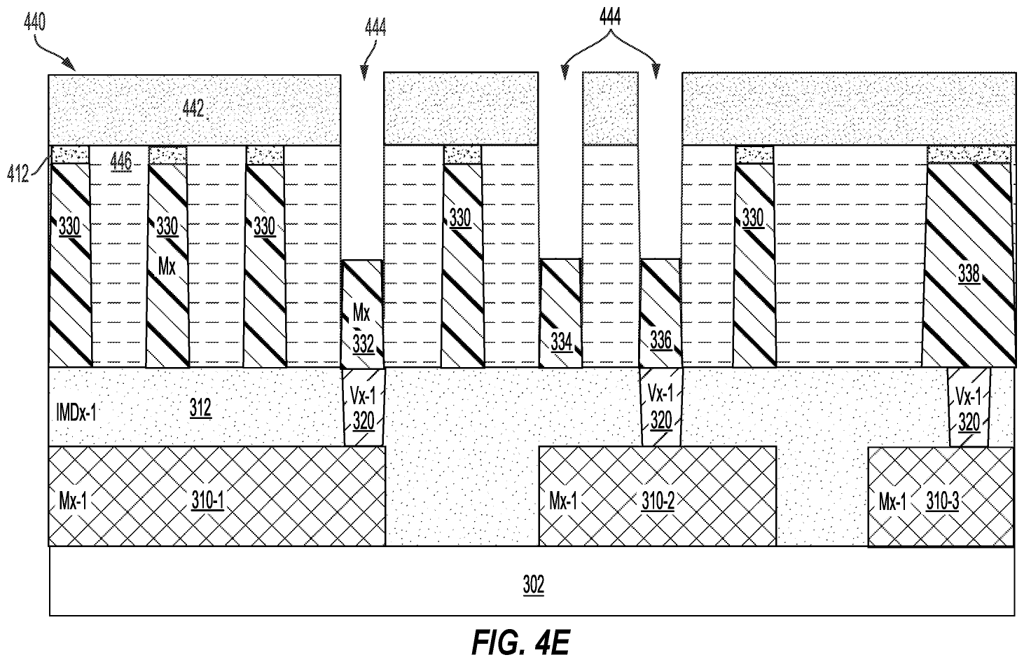

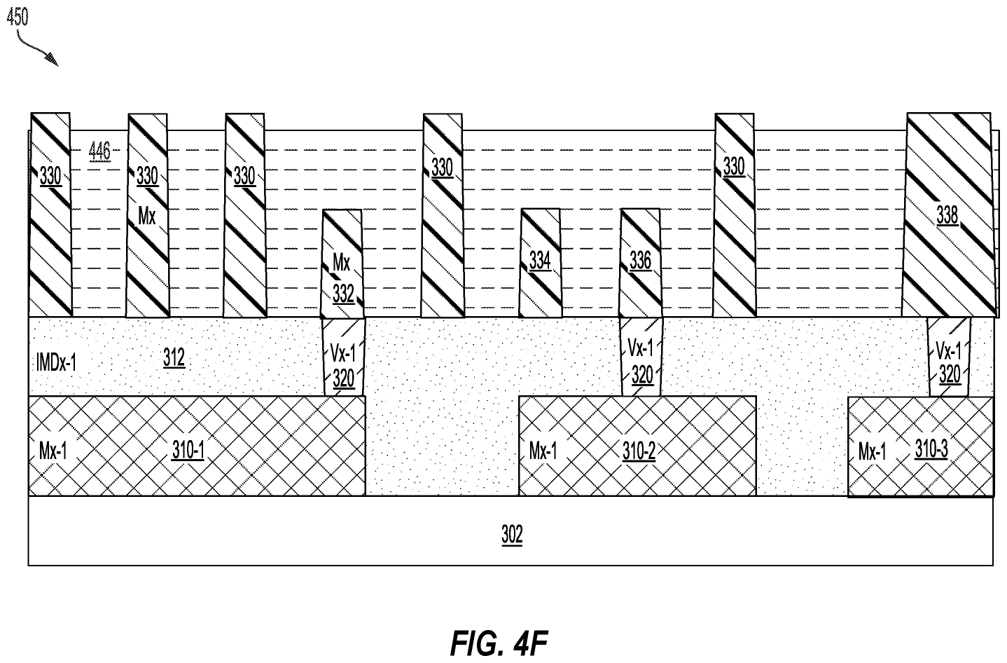

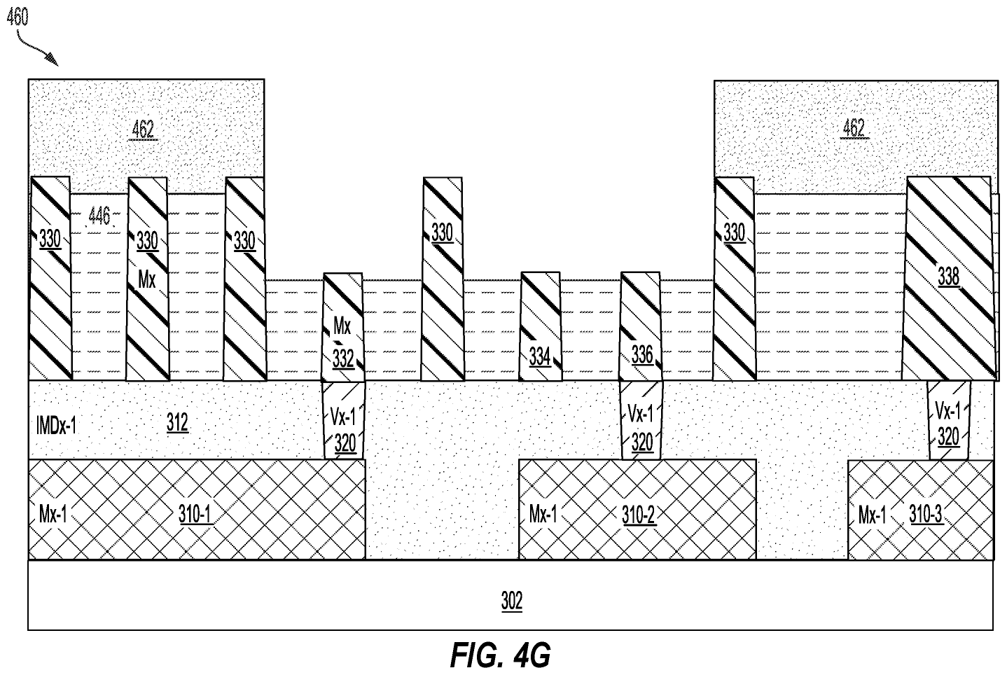

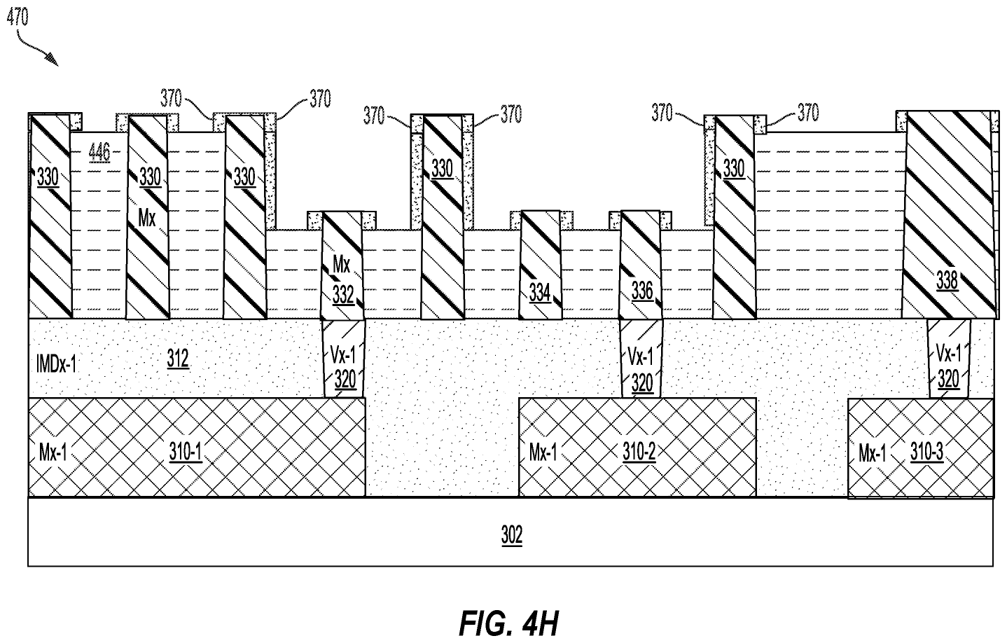

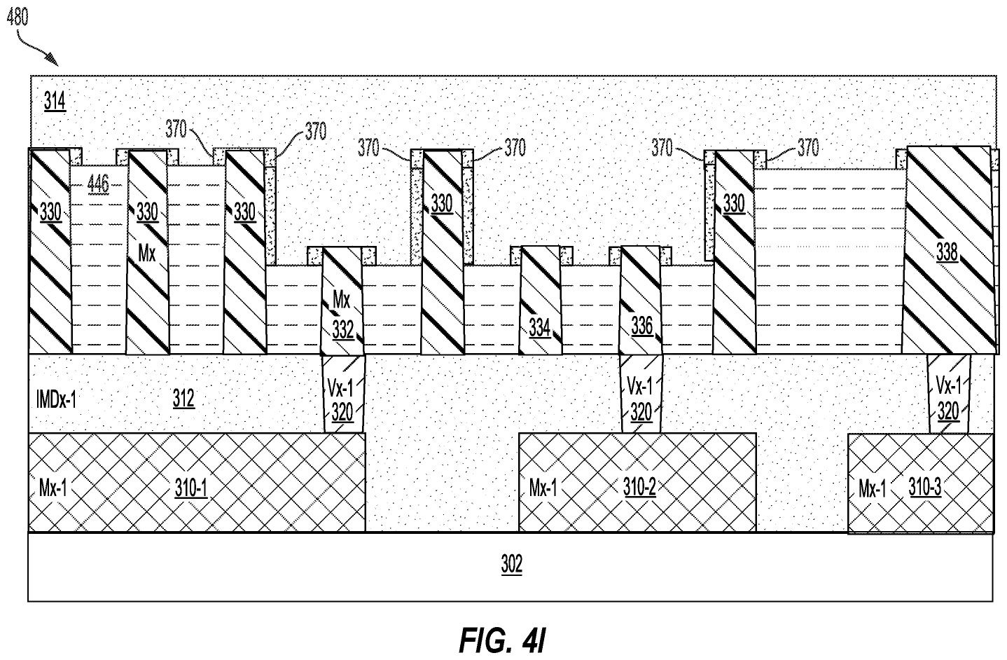

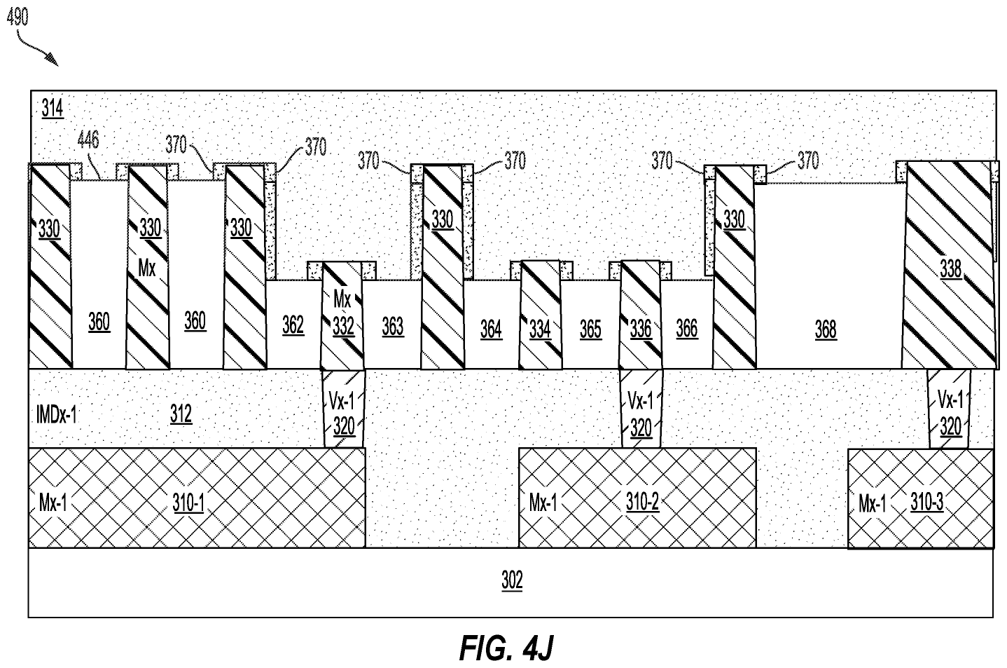

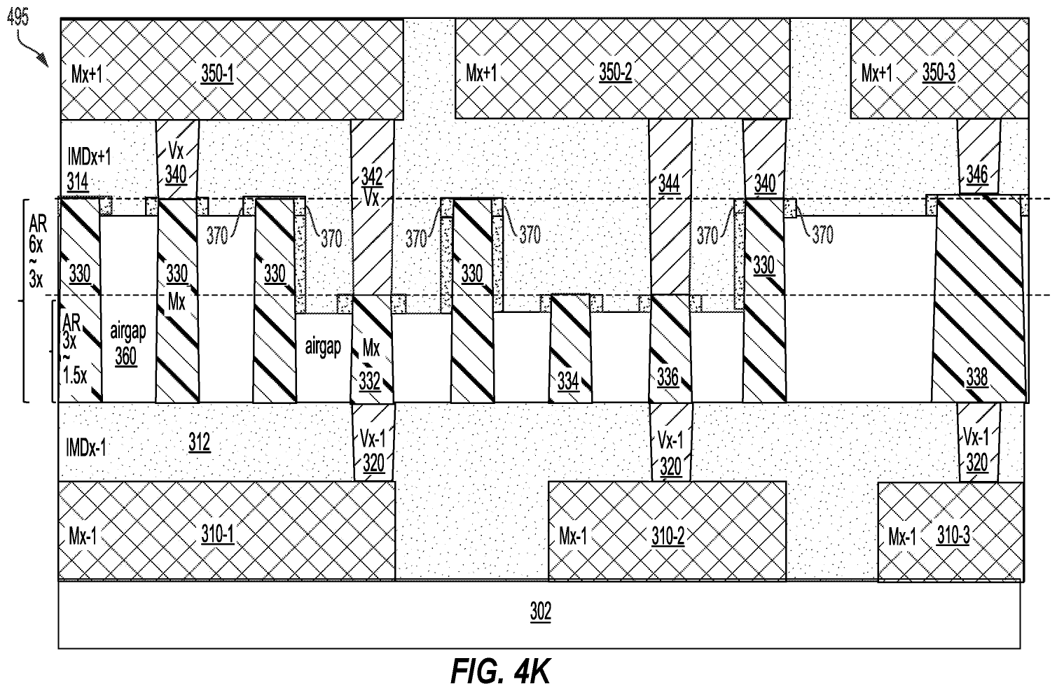

FIGS. 4A-4K are block diagrams illustrating formation of the integrated circuit (IC) device 300, and are described in conjunction with FIG. 3, according to aspects of the present disclosure.

As shown in FIG. 4A, an IC device fabrication process begins at step 400, in which the Mx−1 back-end-of-line (BEOL) interconnects 310 (310-1, 310-2, 310-3) are formed on the substrate 302. Following formation of the Mx−1 BEOL interconnects 310, a first intermetal dielectric film is deposited on the Mx−1 BEOL interconnects 310 to form an IMDx−1 layer 312. Once the IMDx−1 layer 312 is formed, the IMDx−1 layer 312 is patterned to form first BEOL (Vx−1) vias 320. Next, the IMDx−1 layer 312 is planarized using, for example, a chemical mechanical polishing (CMP) process to complete formation of the Vx−1 vias 320 and the IMDx−1 layer 312.

As shown in FIG. 4B, at step 410, a metal film (e.g., one of cobalt (Co), ruthenium (Ru), or tungsten (W)) is deposited on the IMDx−1 layer 312 and patterned to form second BEOL (Mx) interconnects 330, including an expanded Mx interconnect 338 having a different aspect ratio (AR) than the Mx interconnects 330 (e.g., AR 3x-6x). The Mx interconnects 330 may provide metal traces for signal communication in the IC device 300, which are designed with different aspect ratios to improve resistance-capacitance (RC) performance. Additionally, hardmasks 412 are formed on the Mx interconnects 330.

As shown in FIG. 4C, at step 420, a photoresist (PR) layer 422 is deposited on a surface of the IMDx−1 layer 312 and the Mx interconnects 330, and the expanded Mx interconnect 338. Next, the PR layer 422 is patterned to open access areas 424. A metal etching process recesses the Mx interconnects 332, 334, 336 to a reduced height. The reduced height of the Mx interconnects 332, 334, 336 may beneficially enable multiple metal access ratios to reduce a critical metal path resistance.

As shown in FIG. 4D, an optional metal recess step is performed at step 430, in which an oxide layer 436 (e.g., silicon nitride (SiN) is deposited on the surface of the IMDx−1 layer 312 and the Mx interconnects 330, 332, 334, 336, and the expanded Mx interconnect 338. Next, the oxide layer 436 is planarized using, for example, a CMP process, followed by deposition of a PR layer 432 on a surface of the oxide layer 436. The PR layer 432 is patterned and subjected to an additional metal recess etching process to open areas 434 exposing the Mx interconnects 332, 334, 336. Next, the PR layer 432 and the oxide layer 436 are removed to expose the Mx interconnects 330, 332, 334, 336, the expanded Mx interconnect 338, and the IMDx+1 layer 312.

As shown in FIG. 4E, an optional metal recess step is performed at step 440, in which a sacrificial material 446 is deposited on the surface of the IMDx−1 layer 312 and the Mx interconnects 330, 332, 334, 336, and the expanded Mx interconnect 338, 338, followed by deposition of a PR layer 442 on a surface of the sacrificial material 446 and the hardmasks 412 of the Mx interconnects 330, 332, 334, 336, and the expanded Mx interconnect 338. The PR layer 442 is patterned to open areas 444 using a metal recess etching process to expose the Mx interconnects 332, 334, and 336. Next, the PR layer 442 and the hardmasks 412 are removed and the sacrificial material 446 is recessed.

As shown in FIG. 4F, at step 450, an additional layer of the sacrificial material 446 is deposited to fill the open areas 444 (see FIG. 4E) exposing the Mx interconnects 332, 334, 336. Additionally, portions of the Mx interconnects 330 and the expanded Mx interconnect 338 are exposed through the sacrificial material 446. As shown in FIG. 4G, at step 460, PR layers 462 are deposited on the exposed portions of the Mx interconnects 330, the expanded Mx interconnect 338, and the sacrificial material 446. Next, the sacrificial material 446 is subjected to a recess etching process to expose the Mx interconnects 332, 334, 336, as well as one of the Mx interconnects 330.

As shown in FIG. 4H, at step 470, the PR layers 462 are removed to expose sidewall portions of each of the Mx interconnects 330, 332, 334, 336, 338. Next, a film (e.g., SiN) is deposited on the exposed sidewall portions of the Mx interconnects 330, 332, 334, 336, 338. Once deposited, the film is subjected to an anisotropic etch to form etch stop spacers 370, which may be referred to as metal trace corner protection structures. As shown in FIG. 4I, at step 480, a thin IMDx+1 oxide layer (e.g., 20-100 nanometers) is deposited, then the sacrificial material 446 is subjected to a continual thermal removal process. Subsequently, the IMDx+1 layer 314 is deposited and subjected to a CMP planarization process.

As shown in FIG. 4J, at step 490, removal of the sacrificial material 446 provides airgaps 360, 362, 363, 364, 365, 366, 367, 368, which are shown as airgaps of varying heights, according to some aspects of the present disclosure. In this example, the airgaps 360 have similar heights and dimensions. Similarly, second airgaps 362. 363, 364, 365, 366, 368 also have similar heights and dimensions. A third airgap 368 has a similar height, but a greater width than the other airgaps 360, 362, 363, 364, 365, 366, which helps increase an airgap metal capacitance reduction. As shown in FIG. 4K, at step 495, the Mx+1 interconnects 350 (350-1, 350-2, 350-3) and the Vx vias 340 342, 344, 346 are patterned and filled to complete formation of the IC device 300, as shown in FIG. 3.

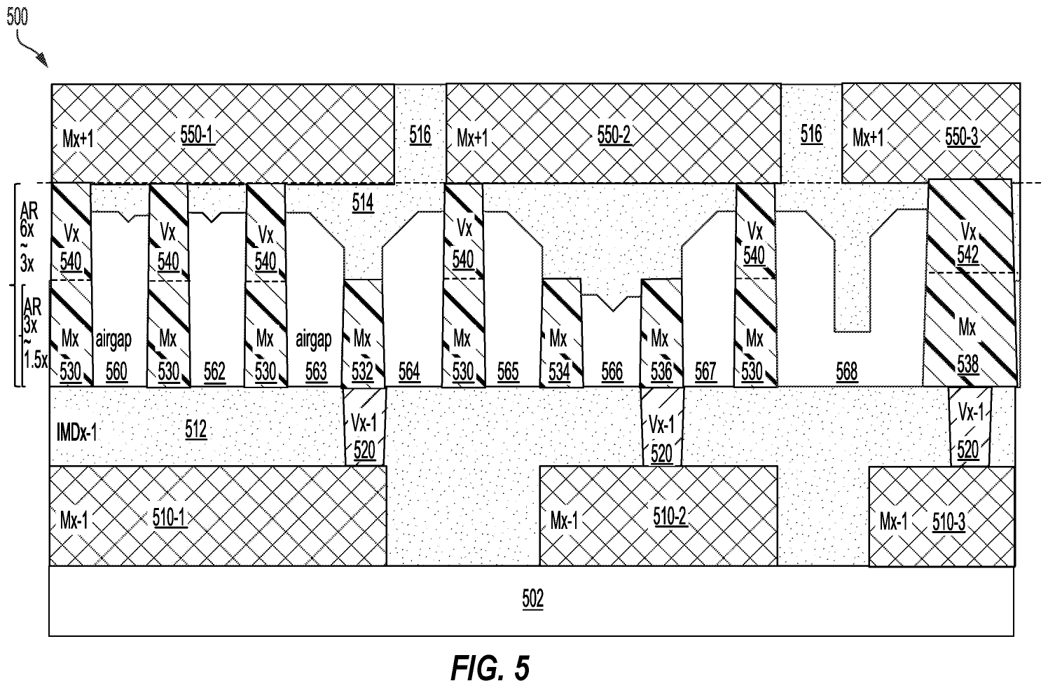

FIG. 5 shows a cross-sectional view illustrating an integrated circuit (IC) device 500, having back-end-of-line (BEOL) interconnects with different airgap shapes, according to aspects of the present disclosure. The IC device 500 includes a semiconductor substrate (e.g., a silicon wafer) 502 on which first BEOL (Mx−1) interconnects 510 (510-1, 510-2, 510-3) are formed. In some aspects of the present disclosure, the IC device 500 includes second BEOL (Mx) interconnects 530, 532, 534, 536, 538 on a first intermetal dielectric (IMDx−1) layer 512 and coupled to the Mx−1 interconnects 510 through first BEOL (Vx) vias 540, 542 in the IMDx−1 layer 512.

In some aspects of the present disclosure, the IC device 500 includes a second IMD (IMDx) layer 514 on the Mx interconnects 530, 532, 534, 536, and an expanded Mx interconnect 538 to seal airgaps 560, 562, 563, 564, 565, 566, 567, 568 of various shapes between the Mx interconnects 530. In some aspects of the present disclosure, the IC device 500 includes the airgaps 560, 562, 563, 564, 565, 566, 567, 568 of various shapes, which increase an airgap metal capacitance reduction. Additionally, the various airgap shapes enable a significant BEOL resistance-capacitance RC reduction. The IC device 500 also includes third BEOL (Mx+1) interconnects 550 (550-1, 550-2, 550-3) in a third IMD (Mx+1) layer 516 on the IMDx layer 514 and coupled to some of the Mx interconnects 530, 532, 534, 536, and the expanded Mx interconnect 538 through second BEOL (Vx) vias 540, 542 in the IMDx layer 514.

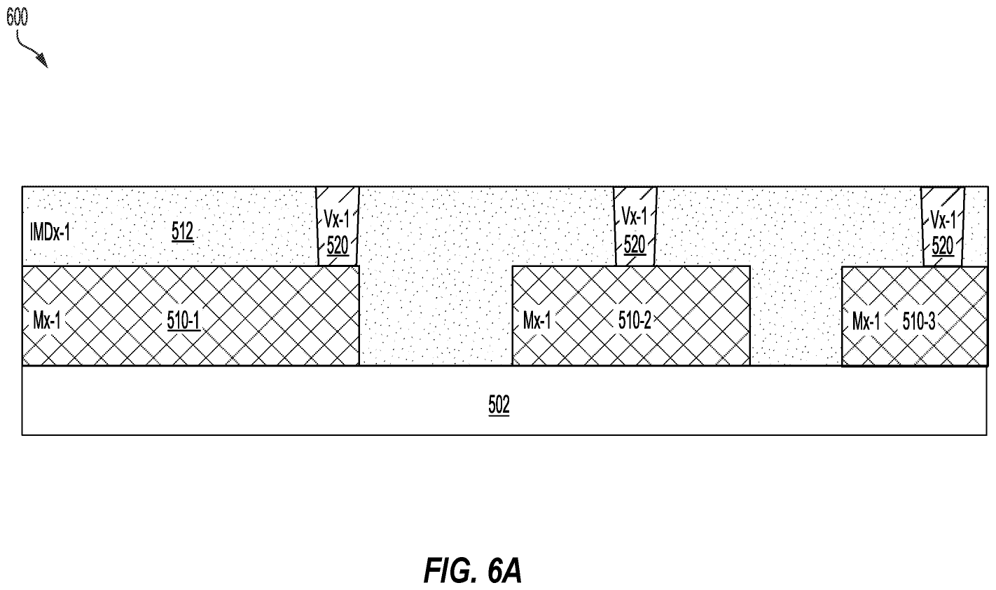

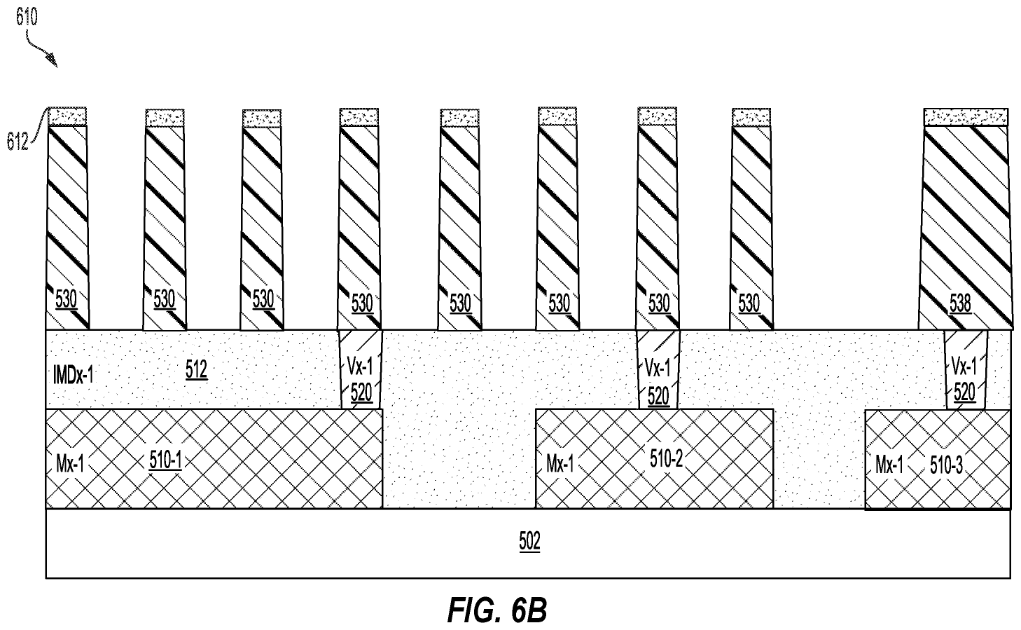

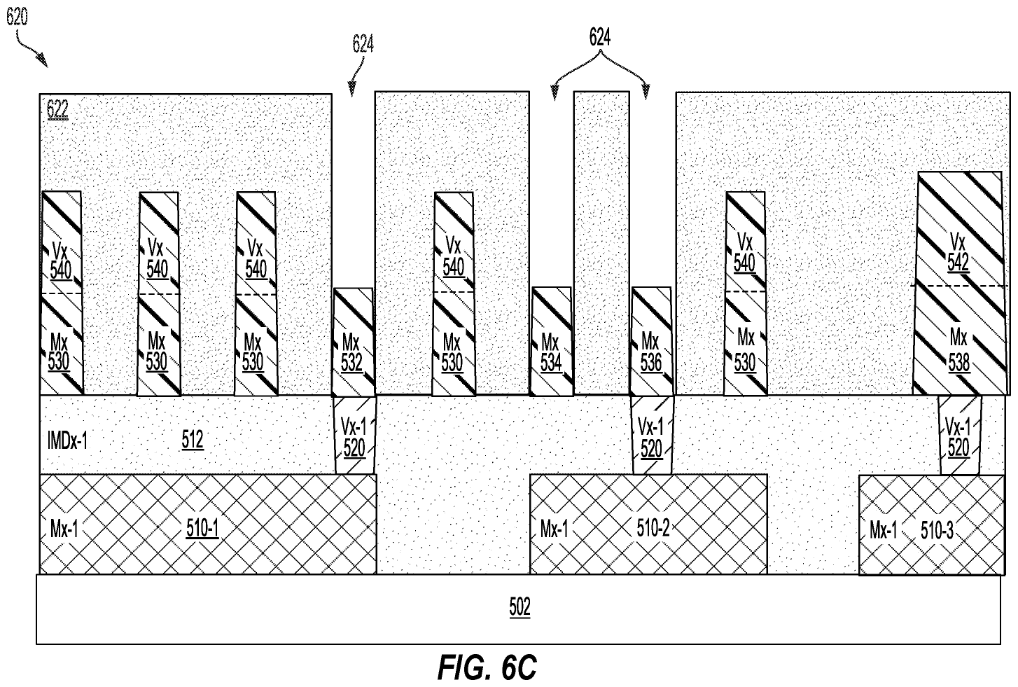

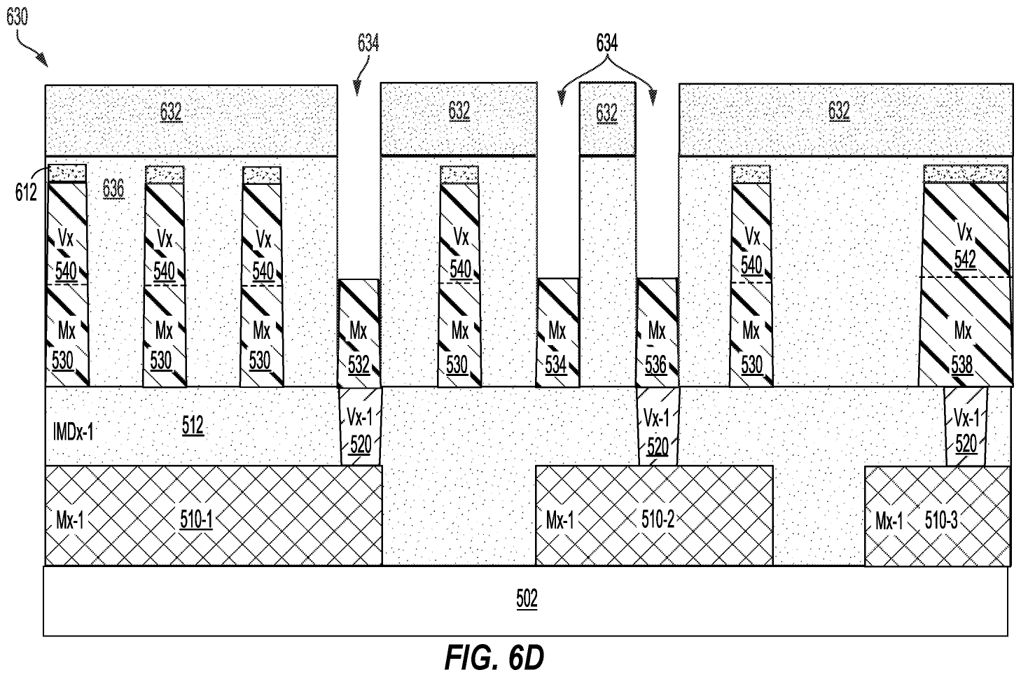

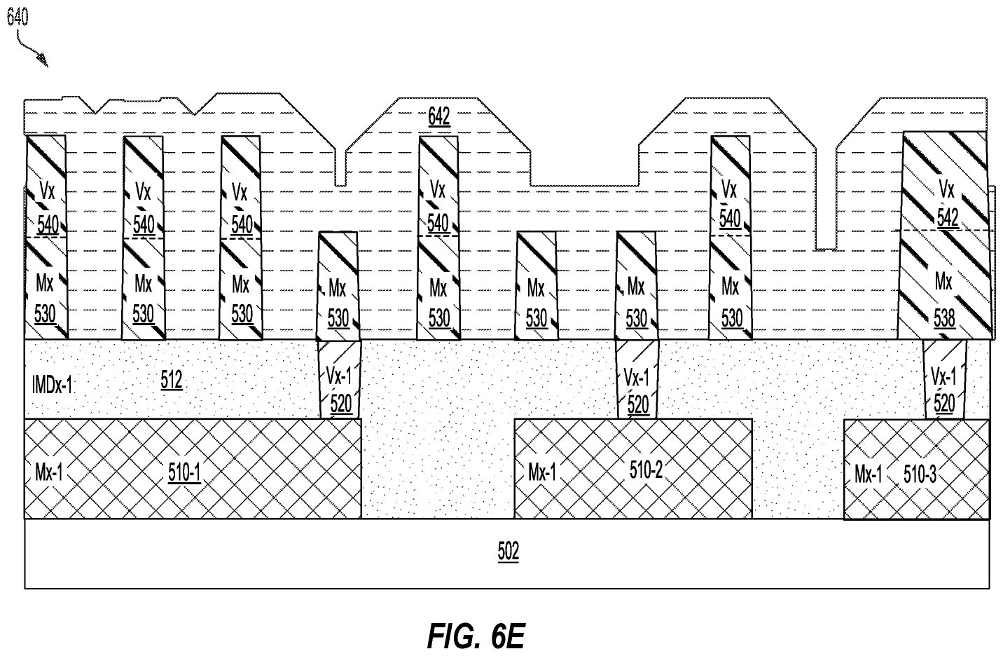

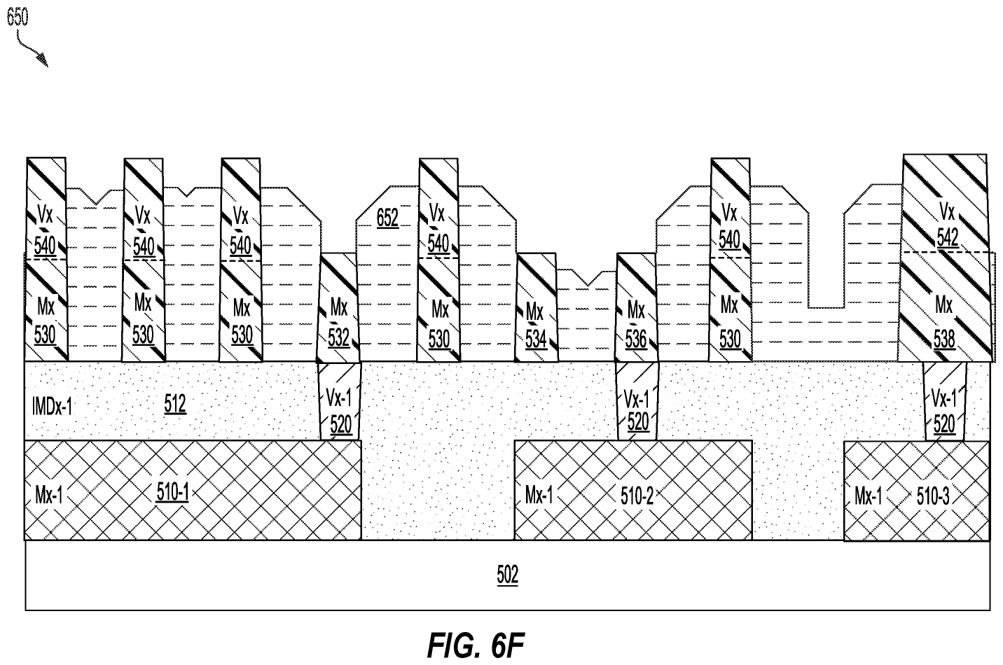

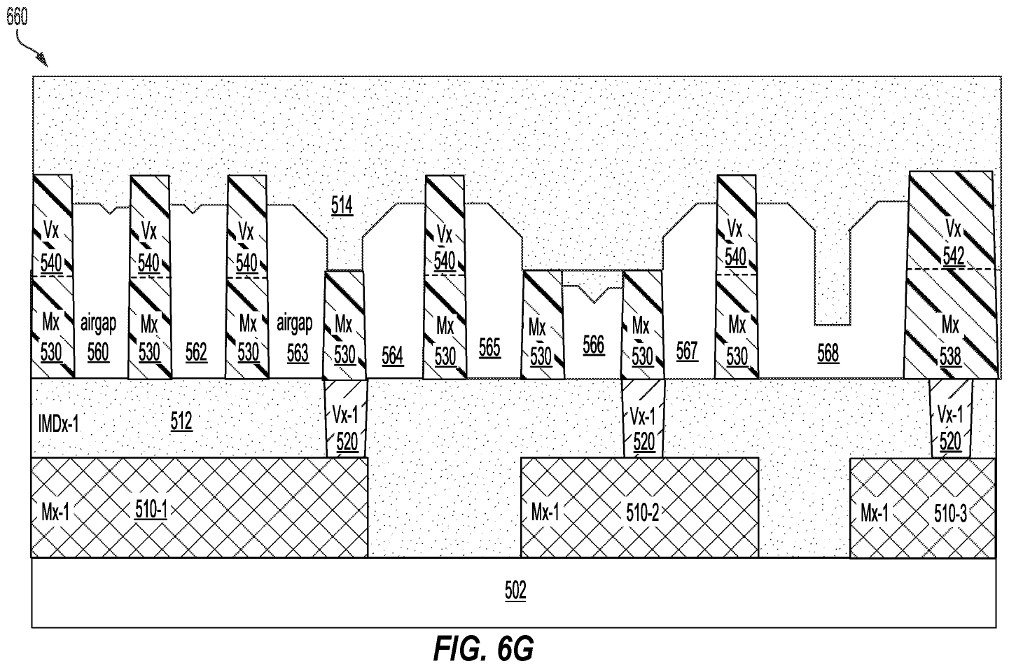

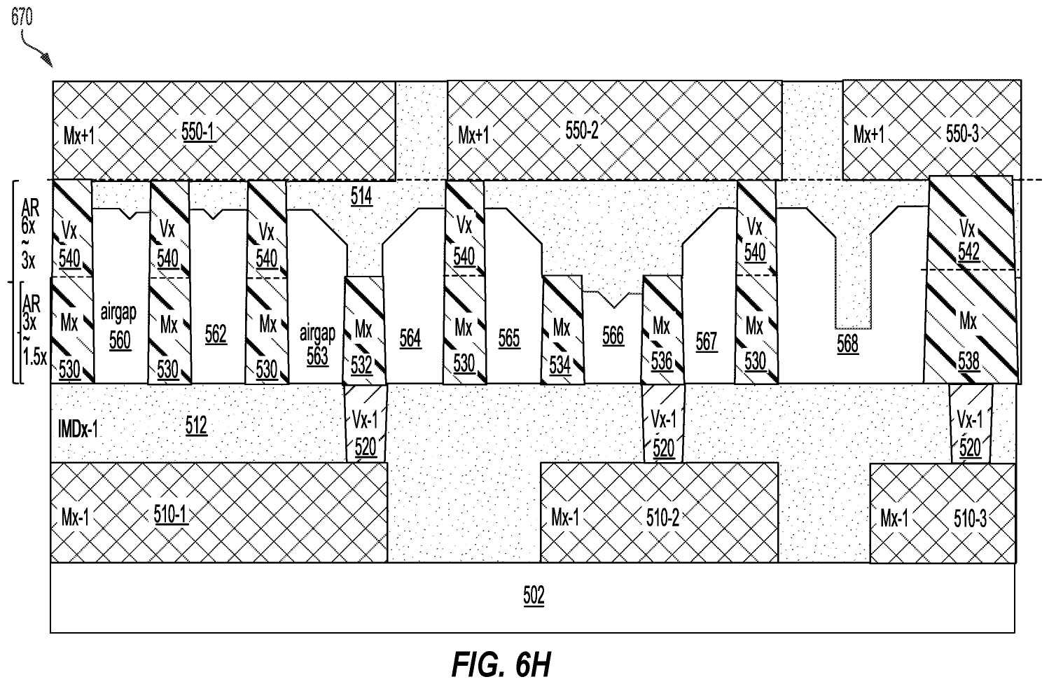

FIG. 6A-6H are cross-sectional diagrams illustrating formation of the integrated circuit (IC) device 500, and are described in conjunction with FIG. 5, according to aspects of the present disclosure.

As shown in FIG. 6A, an IC device fabrication process begins at step 600, in which the Mx−1 interconnects 510 (510-1, 510-2, 510-3) are formed on the substrate 502. Following formation of the Mx−1 interconnects 510, a first intermetal dielectric film is deposited on the Mx−1 interconnects 510 to form an IMDx−1 layer 512. Once the IMDx−1 layer 512 is formed, the IMDx−1 layer 512 is patterned to form first (Vx−1) via openings 520. Next, the Vx−1 via openings 520 are filled and the IMDx−1 layer 512 is planarized using, for example, a chemical mechanical polishing (CMP) process to complete formation of the Vx−1 via openings 520.

As shown in FIG. 6B, at step 610, a metal film (e.g., ruthenium (Ru)) is deposited on the IMDx−1 layer 512 and patterned to form second BEOL (Mx) interconnects 530, including an expanded Mx interconnect 538 having a different aspect ratio (AR) than the Mx interconnects 530 (e.g., AR 4x-6x). The Mx interconnects 530 may provide metal traces for signal communication in the IC device 500, which are designed with different aspect ratios to improve resistance-capacitance (RC) performance. Additionally, hardmasks 612 are formed on the Mx interconnects 530, and the expanded Mx interconnect 538.

As shown in FIG. 6C, at step 620, second BEOL (Vx) vias 540, 542 are formed on the Mx interconnects 530, and the expanded Mx interconnect 538. As further shown in FIG. 6C, a photoresist (PR) layer 622 is deposited on a surface of the IMDx−1 layer 512, the Mx interconnects 530, 538, and the Vx vias 540, 542. Next, the PR layer 622 is patterned to open access areas 624. A metal etching process is performed to recess the Mx interconnects 532, 534, and 536 to remove the Vx vias 540. The reduced height of the Mx interconnects 532, 534, 536 may beneficially enable multiple metal access ratios to reduce a critical metal path resistance.

As shown in FIG. 6D, an option step to recess metal is performed at step 630, in which an oxide layer 636 (e.g., silicon nitride (SiN)) is deposited on the surface of the IMDx−1 layer 512, the Mx interconnects 530, 532, 534, 536, and the expanded Mx interconnect 538, and the Vx vias 540, 542. Next, the oxide layer 636 is planarized using, for example, a CMP process, followed by deposition of a PR layer 632 on a surface of the oxide layer 636. The PR layer 632 is patterned and subjected to an additional metal recess etching process to open areas 634 exposing the Mx interconnects 532, 534, and 536. Next, the PR layer 632 and the oxide layer 636 are removed to expose the Vx vias 540, 542, the Mx interconnects 530, 532, 534, 536, 538, and the IMDx+1 layer 512.

As shown in FIG. 6E, at step 640, a conformal deposition of a sacrificial material 642 is performed on the surface of the IMDx−1 layer 512, the metal/via pattern of the Vx vias 540,542, the Mx interconnects 530, 532, 534, 536, and the expanded Mx interconnect 538. As shown in FIG. 6F, at step 650, the sacrificial material 642 is subjected to a recess etching process to expose portions of the Vx vias 540, 542 the Mx interconnects 532, 534, 536 and the expanded Mx interconnect 538, as well as the Mx interconnects 530. The recess etching adapts a shape of the sacrificial material 642 along the metal/via pattern to form a sacrificial material layer 652.

As shown in FIG. 6G, at step 660, the IMDx layer 514 is deposited on the sacrificial material layer 652 and subjected to a CMP planarization process. Additionally, the sacrificial material layer 652 is subjected to a thermal removal process. In some aspects of the present disclosure, removal of the sacrificial material layer 652 provides multiple shapes for the airgaps 560, 562, 563, 564, 565, 566, 567, 568 or airgaps of varying shapes. In this example, each of the airgaps 560, 562, 563, 564, 565, 566, 567, 568 have different shapes, with different heights and dimensions, which helps increase an airgap metal capacitance reduction. As shown in FIG. 6H, at step 670, the Mx+1 interconnects 550 (550-1, 550-2, 550-3) are patterned and filled to complete formation of the IC device 500, as shown in FIG. 5.

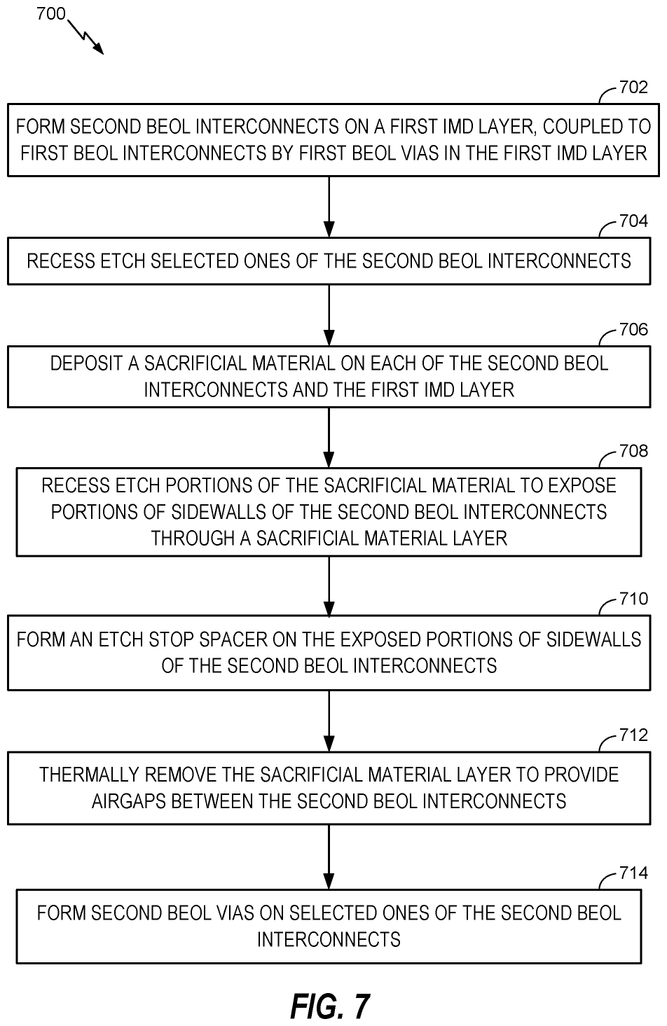

FIG. 7 is a process flow diagram illustrating a method for fabricating back-end-of-line (BEOL) interconnects with different airgap heights and metal trace corner protection structures, according to aspects of the present disclosure. A method 700 begins at block 702, in which second back-end-of-line (BEOL) interconnects are formed on a first intermetal dielectric (IMD) layer, coupled to first BEOL interconnects by first BEOL vias in the first IMD layer. For example, as shown in FIG. 4A, Mx−1 back-end-of-line (BEOL) interconnects 310 (310-1, 310-2, 310-3) are formed on the substrate 302. Following formation of the Mx−1 BEOL interconnects 310, a first intermetal dielectric film is deposited on the Mx−1 BEOL interconnects 310 to form an IMDx−1 layer 312. Once the IMDx−1 layer 312 is formed, the IMDx−1 layer 312 is patterned to form first BEOL (Vx−1) vias 320. Next, the IMDx−1 layer 312 is planarized using, for example, a chemical mechanical polishing (CMP) process to complete formation of the Vx−1 vias 320 and the IMDx−1 layer 312.

At block 704, selected ones of the second BEOL interconnects are recess etched. For example, as shown in FIG. 4C, at step 420, a photoresist (PR) layer 422 is deposited on a surface of the IMDx−1 layer 312 and the Mx interconnects 330, and the expanded Mx interconnect 338. Next, the PR layer 422 is patterned to open access areas 424. A metal etching process recesses the Mx interconnects 332, 334, 336 to a reduced height. The reduced height of the Mx interconnects 332, 334, 336 may beneficially enable multiple metal access ratios to reduce a critical metal path resistance.

At block 706, a sacrificial material is deposited on each of the second BEOL interconnects and the first IMD layer. For example, as shown in FIG. 4E, a sacrificial material 446 is deposited on the surface of the IMDx−1 layer 312 and the Mx interconnects 330, 332, 334, 336, and the expanded Mx interconnect 338, 338, followed by deposition of a PR layer 442 on a surface of the sacrificial material 446 and the hardmasks 412 of the Mx interconnects 330, 332, 334, 336, and the expanded Mx interconnect 338. The PR layer 442 is patterned to open areas 444 using a metal recess etching process to expose the Mx interconnects 332, 334, and 336. Next, the PR layer 442 and the hardmasks 412 are removed and the sacrificial material 446 is recessed.

At block 708, portions of the sacrificial material recess etched to expose portions of sidewalls of the second BEOL interconnects through a sacrificial material layer. For example, as shown in FIG. 4G, at step 460, PR layers 462 are deposited on the exposed portions of the Mx interconnects 330, the expanded Mx interconnect 338, and the sacrificial material 446. Next, the sacrificial material 446 is subjected to a recess etching process to expose the Mx interconnects 332, 334, 336, as well as one of the Mx interconnects 330.

At block 710, an etch stop spacer is formed on the exposed portions of sidewalls of the second BEOL interconnects. For example, as shown in FIG. 4H, at step 470, the PR layers 462 are removed to expose sidewall portions of each of the Mx interconnects 330, 332, 334, 336, 338. Next, a film (e.g., SiN) is deposited on the exposed sidewall portions of the Mx interconnects 330, 332, 334, 336, 338. Once deposited, the film is subjected to an anisotropic etch to form etch stop spacers 370, which may be referred to as metal trace corner protection structures.

At block 712, the sacrificial material layer is thermally removed to provide airgaps between the second BEOL interconnects. For example, as shown in FIG. 4J, at step 490, removal of the sacrificial material 446 provides airgaps 360, 362, 363, 364, 365, 366, 367, 368, which are shown as airgaps of varying heights, according to some aspects of the present disclosure. As shown in FIG. 6G, at step 660, the IMDx layer 514 is deposited on the sacrificial material layer 652 and subjected to a CMP planarization process. Additionally, the sacrificial material layer 652 is subjected to a thermal removal process, providing multiple shapes for the airgaps 560, 562, 563, 564, 565, 566, 567, 568 or airgaps of varying shapes. In this example, each of the airgaps 560, 562, 563, 564, 565, 566, 567, 568 have different shapes, with different heights and dimensions, which helps increase an airgap metal capacitance reduction.

At block 714, second BEOL vias are formed on selected ones of the second BEOL interconnects. For example, as shown in FIG. 4K, at step 495, the Mx+1 interconnects 350 (350-1, 350-2, 350-3) and the Vx vias 340 342, 344, 346 are patterned and filled to complete formation of the IC device 300, as shown in FIG. 3. As shown in FIG. 6H, at step 670, the Mx+1 interconnects 550 (550-1, 550-2, 550-3) are patterned and filled to complete formation of the IC device 500, as shown in FIG. 5.

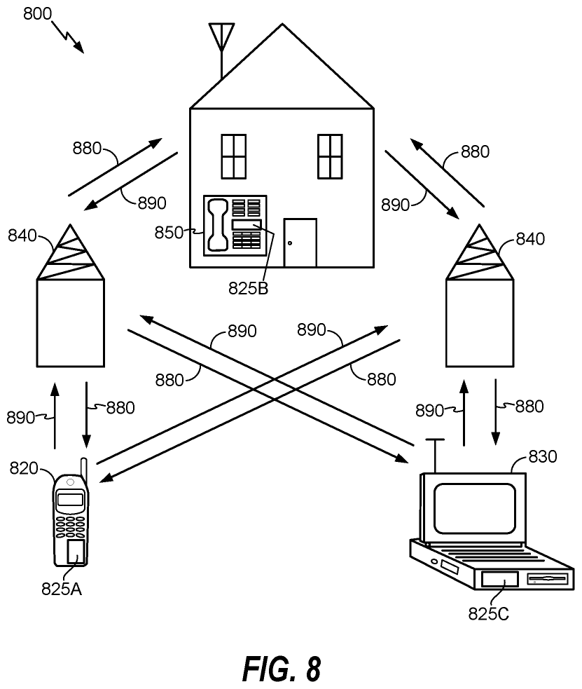

FIG. 8 is a block diagram showing an exemplary wireless communications system 800 in which an aspect of the disclosure may be advantageously employed. For purposes of illustration, FIG. 8 shows three remote units 820, 830, and 850, and two base stations 840. It will be recognized that wireless communications systems may have many more remote units and base stations. Remote units 820, 830, and 850 include integrated circuit (IC) devices 825A, 825C, and 825B that include the disclosed BEOL interconnect with different airgap heights and metal trace corner protection structure. It will be recognized that other devices may also include the disclosed BEOL interconnect with different airgap heights and metal trace corner protection structure, such as the base stations 840, switching devices, and network equipment. FIG. 8 shows forward link signals 880 from the base stations 840 to the remote units 820, 830, and 850, and reverse link signals 890 from the remote units 820, 830, and 850 to base stations 840.

In FIG. 8, remote unit 820 is shown as a mobile telephone, remote unit 830 is shown as a portable computer, and remote unit 850 is shown as a fixed location remote unit in a wireless local loop system. For example, the remote units may be a mobile phone, a hand-held personal communications systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 8 illustrates remote units according to aspects of the present disclosure, the disclosure is not limited to these exemplary illustrated units. Aspects of the present disclosure may be suitably employed in many devices, which include the disclosed BEOL interconnect with different airgap heights and metal trace corner protection structure.

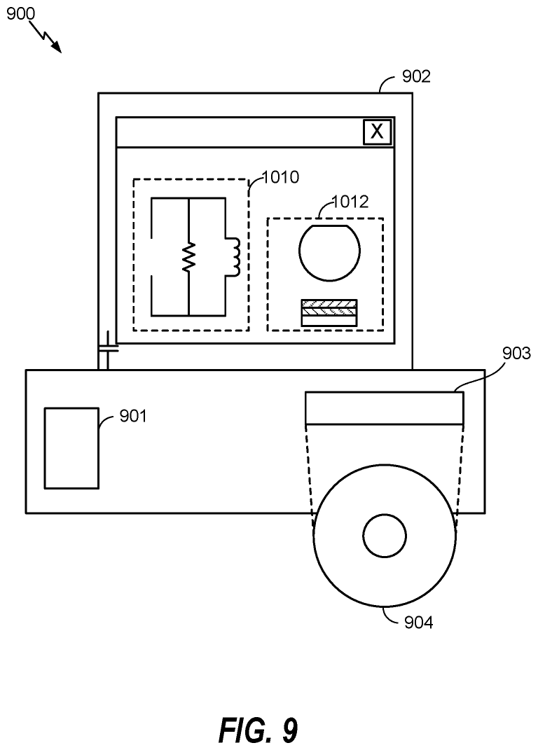

FIG. 9 is a block diagram illustrating a design workstation used for circuit, layout, and logic design of a semiconductor component, such as the capacitors disclosed above. A design workstation 900 includes a hard disk 901 containing operating system software, support files, and design software such as Cadence or OrCAD. The design workstation 900 also includes a display 902 to facilitate design of a circuit 910 or an integrated circuit (IC) component 912 such as a BEOL interconnect with different airgap heights and metal trace corner protection structure. A storage medium 904 is provided for tangibly storing the design of the circuit 910 or the IC component 912 (e.g., the BEOL interconnect with different airgap heights and metal trace corner protection structure). The design of the circuit 910 or the IC component 912 may be stored on the storage medium 904 in a file format such as GDSII or GERBER. The storage medium 904 may be a CD-ROM, DVD, hard disk, flash memory, or other appropriate device. Furthermore, the design workstation 900 includes a drive apparatus 903 for accepting input from or writing output to the storage medium 904.

Data recorded on the storage medium 904 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 904 facilitates the design of the circuit 910 or the IC component 912 by decreasing the number of processes for designing semiconductor wafers.

Implementation examples are described in the following numbered clauses:
1. An integrated circuit (IC), comprising:
a plurality of first back-end-of-line (BEOL) interconnects in a first intermetal dielectric (IMD) layer on a substrate;
a plurality of second BEOL interconnects on the first IMD layer, coupled to the first BEOL interconnects through first BEOL vias in the first IMD layer;
a second IMD layer on the plurality of second BEOL interconnects to seal airgaps between the plurality of second BEOL interconnects;
etch stop spacers on portions of sidewalls of the second BEOL interconnects to separate the portions of the sidewalls from the second IMD layer; and
a plurality of third BEOL interconnects on the second IMD layer and coupled to one or more of the second BEOL interconnects through second BEOL vias in the second IMD layer.
2. The IC of clause 1, in which a height of one of the airgaps is greater than a height of another of the airgaps.
3. The IC of clause 1, in which a shape of one of the airgaps is different than a shape of another of the airgaps.
4. The IC of any of clauses 1-3, in which a height of one of the second BEOL vias is greater than a height of another of the second BEOL vias.
5. The IC of any of clauses 1-4, in which a height of one of the second BEOL interconnects is less than a height of another of the second BEOL interconnects.
6. The IC of any of clauses 1-5, in which an aspect ratio of one of the second BEOL interconnects is less than an aspect ratio of another of the second BEOL interconnects.
7. The IC of any of clauses 1-6, in which the second BEOL interconnects comprise ruthenium (Ru).
8. The IC of any of clauses 1-7, in which the second BEOL vias comprise one of cobalt (Co), ruthenium (Ru), or tungsten (W).
9. The IC of any of clauses 1-8, in which the etch stop spacers comprise silicon nitride (SIN).
10. A method for fabricating back-end-of-line (BEOL) interconnects with different airgap heights and metal trace corner protection structures, comprising:
forming a plurality of second back-end-of-line (BEOL) interconnects on a first intermetal dielectric (IMD) layer, coupled to a plurality of first BEOL interconnects by first BEOL vias in the first IMD layer;
recess etching selected ones of the plurality of second BEOL interconnects;
depositing a sacrificial material on each of the second BEOL interconnects and the first IMD layer;
recess etching portions of the sacrificial material to expose portions of sidewalls of the second BEOL interconnects through a sacrificial material layer;
forming an etch stop spacer on the exposed portions of sidewalls of the second BEOL interconnects;
thermally removing the sacrificial material layer to provide airgaps between the plurality of second BEOL interconnects; and
forming second BEOL vias on selected ones of the second BEOL interconnects.
11. The method of clause 10, in which depositing the sacrificial material comprises performing a conformal deposition of the sacrificial material on each of the second BEOL interconnects and the first IMD layer.
12. The method of clause 10 in which forming the second BEOL vias comprises:
depositing a second IMD layer on the plurality of second BEOL interconnects in the sacrificial material layer;
etching the second IMD layer to expose the selected ones of the second BEOL interconnects through second BEOL via openings; and
filling the second BEOL via openings to form the second BEOL vias on selected ones of the second BEOL interconnects.
13. The method of any of clauses 10-12, further comprising forming a plurality of third BEOL interconnects on a second IMD layer and coupled to one or more of the second BEOL interconnects through the second BEOL vias in the second IMD layer.
14. The method of any of clauses 10-13, in which a height of one of the airgaps is greater than a height of another of the airgaps.
15. The method of any of clauses 10-13, in which a shape of one of the airgaps is different than a shape of another of the airgaps.
16. The method of any of clauses 10-15, in which a height of one of the second BEOL vias is greater than a height of another of the second BEOL vias.
17. The method of any of clauses 10-16, in which a height of one of the second BEOL interconnects is less than a height of another of the second BEOL interconnects.
18. The method of any of clauses 10-17, in which an aspect ratio of one of the second BEOL interconnects is less than an aspect ratio of another of the second BEOL interconnects.
19. The method of any of clauses 10-18, in which the second BEOL interconnects comprise ruthenium (Ru).
20. The method of any of clauses 10-19, in which the second BEOL vias comprise one of cobalt (Co), ruthenium (Ru), or tungsten (W).

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer. Disk and disc, as used herein, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the configurations of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An integrated circuit (IC), comprising:
a plurality of first back-end-of-line (BEOL) interconnects in a first intermetal dielectric (IMD) layer on a substrate;
a plurality of second BEOL interconnects on the first IMD layer, coupled to the first BEOL interconnects through first BEOL vias in the first IMD layer;
a second IMD layer on the plurality of second BEOL interconnects to seal airgaps between the plurality of second BEOL interconnects;
etch stop spacers on portions of sidewalls of the second BEOL interconnects to separate the portions of the sidewalls from the second IMD layer; and
a plurality of third BEOL interconnects on the second IMD layer and coupled to one or more of the second BEOL interconnects through second BEOL vias in the second IMD layer.

2. The IC of claim 1, in which a height of one of the airgaps is greater than a height of another of the airgaps.

3. The IC of claim 1, in which a shape of one of the airgaps is different than a shape of another of the airgaps.

4. The IC of claim 1, in which a height of one of the second BEOL vias is greater than a height of another of the second BEOL vias.

5. The IC of claim 1, in which a height of one of the second BEOL interconnects is less than a height of another of the second BEOL interconnects.

6. The IC of claim 1, in which an aspect ratio of one of the second BEOL interconnects is less than an aspect ratio of another of the second BEOL interconnects.

7. The IC of claim 1, in which the second BEOL interconnects comprise ruthenium (Ru).

8. The IC of claim 1, in which the second BEOL vias comprise one of cobalt (Co), ruthenium (Ru), or tungsten (W).

9. The IC of claim 1, in which the etch stop spacers comprise silicon nitride (SiN).

10. A method for fabricating back-end-of-line (BEOL) interconnects with different airgap heights and metal trace corner protection structures, comprising:
forming a plurality of second back-end-of-line (BEOL) interconnects on a first intermetal dielectric (IMD) layer, coupled to a plurality of first BEOL interconnects by first BEOL vias in the first IMD layer;
recess etching selected ones of the plurality of second BEOL interconnects;
depositing a sacrificial material on each of the second BEOL interconnects and the first IMD layer;
recess etching portions of the sacrificial material to expose portions of sidewalls of the second BEOL interconnects through a sacrificial material layer;
forming an etch stop spacer on the exposed portions of sidewalls of the second BEOL interconnects;
thermally removing the sacrificial material layer to provide airgaps between the plurality of second BEOL interconnects; and
forming second BEOL vias on selected ones of the second BEOL interconnects.

11. The method of claim 10, in which depositing the sacrificial material comprises performing a conformal deposition of the sacrificial material on each of the second BEOL interconnects and the first IMD layer.

12. The method of claim 10 in which forming the second BEOL vias comprises:
depositing a second IMD layer on the plurality of second BEOL interconnects in the sacrificial material layer;
etching the second IMD layer to expose the selected ones of the second BEOL interconnects through second BEOL via openings; and
filling the second BEOL via openings to form the second BEOL vias on selected ones of the second BEOL interconnects.

13. The method of claim 10, further comprising forming a plurality of third BEOL interconnects on a second IMD layer and coupled to one or more of the second BEOL interconnects through the second BEOL vias in the second IMD layer.

14. The method of claim 10, in which a height of one of the airgaps is greater than a height of another of the airgaps.

15. The method of claim 10, in which a shape of one of the airgaps is different than a shape of another of the airgaps.

16. The method of claim 10, in which a height of one of the second BEOL vias is greater than a height of another of the second BEOL vias.

17. The method of claim 10, in which a height of one of the second BEOL interconnects is less than a height of another of the second BEOL interconnects.

18. The method of claim 10, in which an aspect ratio of one of the second BEOL interconnects is less than an aspect ratio of another of the second BEOL interconnects.

19. The method of claim 10, in which the second BEOL interconnects comprise ruthenium (Ru).

20. The method of claim 10, in which the second BEOL vias comprise one of cobalt (Co), ruthenium (Ru), or tungsten (W).
